(19) United States
(12) Patent Application Publication
(10) Pub. No.: US 2008/0277761 A1
(43) Pub. Date: Nov. 13, 2008

(54) ON-CHIP ISOLATION CAPACITORS, CIRCUITS THEREFROM, AND METHODS FOR FORMING THE SAME

(75) Inventors: Pushpa Mahalingam, Richardson, TX (US); David C. Guiling, Garland, TX (US); Sunny K. Lee, Garland, TX (US); Ramon F. Figueroa, McKinney, TX (US); Weidong Tian, Dallas, TX (US); Yvonne D. Patton, Plano, TX (US); Imran M. Khan, Richardson, TX (US)

Correspondence Address: TEXAS INSTRUMENTS INCORPORATED, P O BOX 655474, M/S 3999, DALLAS, TX, 75265, US

(73) Assignee: Texas Instruments, Inc.

(21) Appl. No.: 12/022,877

(22) Filed: Jan. 30, 2008

Related U.S. Application Data
(60) Provisional application No. 60/916,699, filed on May 8, 2007.

(51) Int. Cl. H01L 29/00; H01L 21/20

(52) U.S. Cl. 257/532; 438/393; 257/E29.343

(57) ABSTRACT

An integrated circuit includes a substrate having a semiconducting surface, and at least one isolation capacitor on the surface. The capacitor includes a bottom electrically conductive plate in or on the surface, a multi-layer dielectric comprising stack over the bottom plate, and a top electrically conductive plate formed over the dielectric stack. The dielectric stack comprises at least one layer of silicon dioxide and at least one layer of silicon nitride, wherein the layer of silicon nitride is located immediately below or immediately above the top plate.

### CROSS REFERENCE TO RELATED APPLICATIONS

The present application claims the benefit of U.S. Provisional Patent Application No. 60/916,699 filed on May 8, 2007, which is incorporated by reference in its entirety into the present application.

### FIELD OF THE INVENTION

The present invention is related to on-chip isolation capacitors and related integrated circuits, and methods for forming the same.

### BACKGROUND

Circuit isolators block low-frequency signals while allowing analog or digital signal transfer via electromagnetic or optical links between two communicating points. Typically, circuit isolation is used in two general situations. The first is where there is the potential for current surges that may damage equipment or harm people. The second is where interconnections involve different ground potentials and disruptive ground loops are to be avoided. In both cases, isolation can be used to prevent current flow associated with hazardous signals, yet allow for data or power flow between the two communicating points.

Digital isolators transfer binary signals and analog isolators transfer continuous signals across the isolation barrier. In both analog and digital isolators, working and peak voltage ratings and common-mode transient immunity are generally the most significant characteristics of the isolation barrier. When isolating digital signals, the significant characteristics of the isolation circuit are generally input and output logic voltage levels, signaling rate, data run length, and fail-safe responses.

There are three common isolation technologies, optical, transformer and capacitive. Capacitive isolation employs one or more capacitors to couple data signals across the capacitive barrier. The plate size, distance between the plates, and the dielectric material determine the electrical properties of the capacitive isolator, generally referred to herein and known as an isolation capacitor. A time varying electric field transmits information across the isolation capacitor. The material between the electrically conductive capacitor plates is a dielectric and forms the isolation barrier. On-chip isolation capacitors can provide fast data transmission, low power consumption and high magnetic immunity.

In one known on-chip isolation capacitor arrangement, Cu is used as the top plate and the dielectric or dielectric stack between the electrically conductive top and bottom plates comprises exclusively silicon oxide which is provided by the inter-layer dielectric (ILD) for conventional multi-level metal processes. Cu for the top plate generally necessitates the use of polyimide (PI) or benzocyclobutene (BCB) as mold compounds. BCB is known to be susceptible to cracking during packaging & PI can cause bonding issues. Moreover, to obtain high breakdown voltage it may become necessary to increase the thickness of the dielectric. However, thick oxide films (e.g. >12 μm) can cause wafer bow and warp causing alignment and other manufacturability problems thus becoming a practical limit to the oxide thickness and thus the attainable breakdown voltage of the known isolation capacitor.

### SUMMARY

This Summary is provided to comply with 37 C.F.R. §1.73, requiring a summary of the invention briefly indicating the nature and substance of the invention. It is submitted with the understanding that it will not be used to interpret or limit the scope or meaning of the claims.

In one embodiment of the invention an integrated circuit comprises a substrate having a semiconducting surface, and at least isolation capacitor on the surface. The capacitor comprises a bottom electrically conductive plate that is formed in or over the semiconducting surface, a multi-layer dielectric comprising stack over the bottom plate, and a top electrically conductive plate over the dielectric stack. The dielectric stack comprises at least one layer of silicon oxide and at least one layer of silicon nitride, wherein the layer of silicon nitride is located immediately below the top plate and/or immediately above the bottom plate. In one embodiment, the dielectric stack also includes at least one layer of silicon oxynitride.

Silicon oxynitride is herein referred to as SiON but as known in the art is not generally a stoichiometric material. Instead, silicon oxynitride is characterized as having a dielectric comprising silicon, nitrogen and oxygen, generally SiOxNy, x=1.4 to 1.97, y=0.06 to 0.24) and having a dielectric constant of at least 4.4, but less than that of silicon nitride. Silicon nitride is characterized as SiNy (generally y=1.04 to 1.63) generally having a dielectric constant of about 6-8 and as known in the art may include varying amounts of hydrogen.

As defined herein, an isolation capacitive according to embodiments of the invention refers to an on-chip capacitor comprising at least one, and generally a plurality of the integrated circuit metal layers, a dielectric stack comprising two or more dielectric layers having a total dielectric thickness of at least 6 μm, that provides a BVrms of at least 5 kVrms and at least a 6 kV surge. (Electrical measurements referenced herein follow UL 1577, IEC 60747-5-2 and CSA standards).

### DESCRIPTION OF THE DRAWINGS

FIG. 1A shows a cross sectional view of an integrated circuit comprising a capacitive isolator according to an embodiment of the invention.

FIG. 1B shows a cross sectional view of an integrated circuit comprising an isolation capacitor according to another embodiment of the invention.

FIG. 1C shows a cross sectional view of an integrated circuit comprising an isolation capacitor according to another embodiment of the invention.

FIG. 1D shows a cross sectional view of an integrated circuit comprising an isolation capacitor according to yet another embodiment of the invention.

FIG. 1E shows a cross sectional view of an integrated circuit comprising an isolation capacitor according to yet another embodiment of the invention.

FIG. 2A is a block diagram representation of an isolation capacitor comprising circuit according to an embodiment of the invention.

FIG. 2B is a block diagram representation of an isolation capacitor comprising circuit according to another embodiment of the invention.

FIG. 3 shows a block diagram of an isolation capacitor comprising circuit according to an embodiment of the invention implementing signaling across a plurality of isolation capacitors and includes an input network that provides a non-encoded high signaling rate channel and a low signaling rate encoded channel in a pulse width modulated (PWM) format.

### DETAILED DESCRIPTION

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

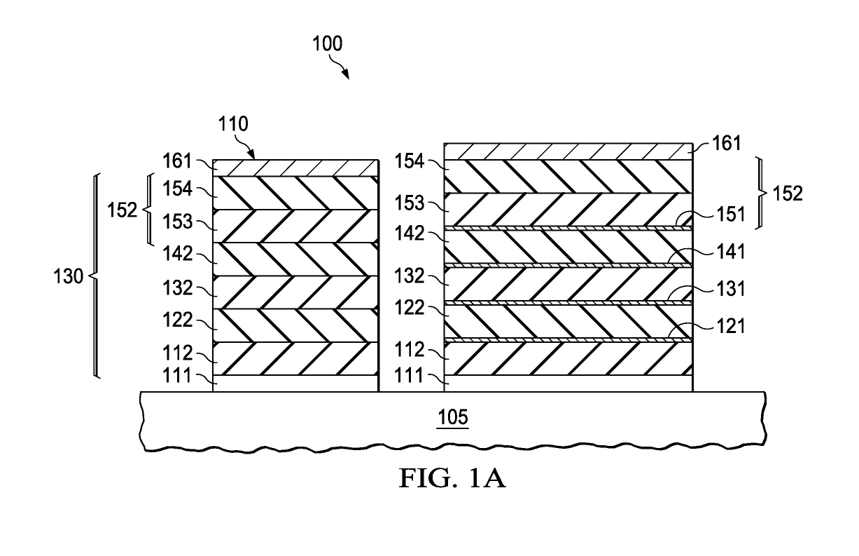

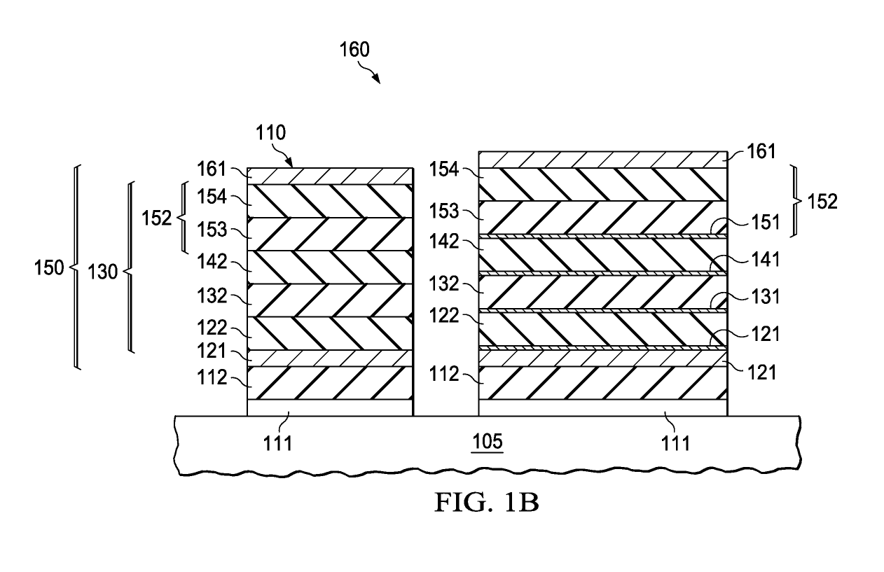

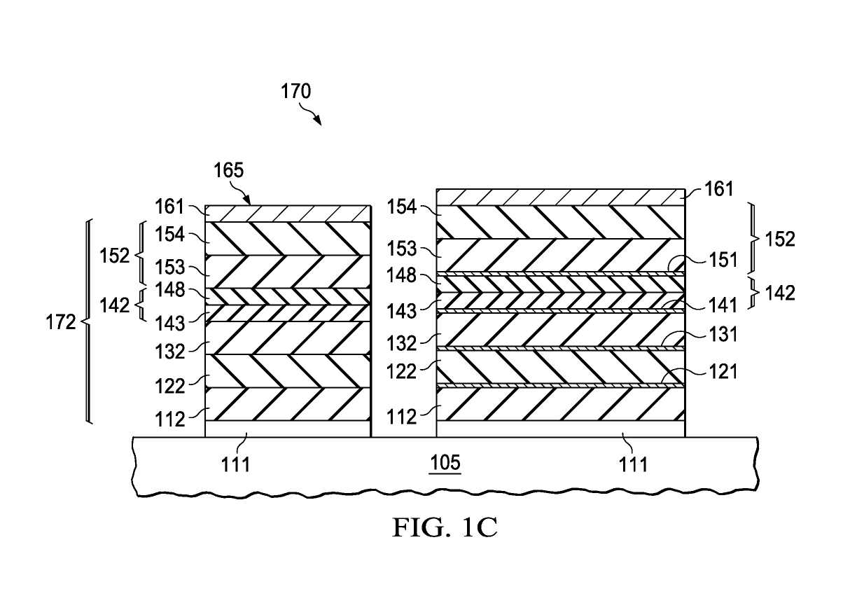

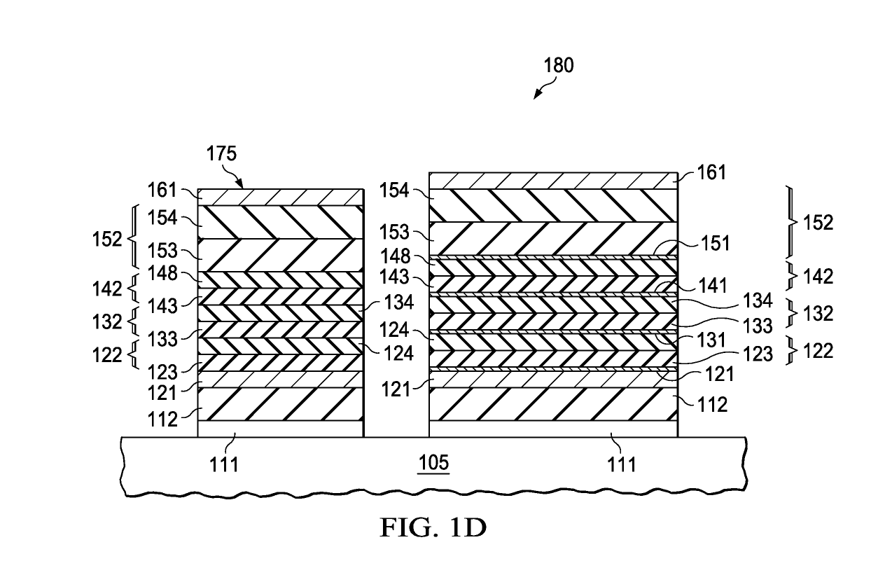

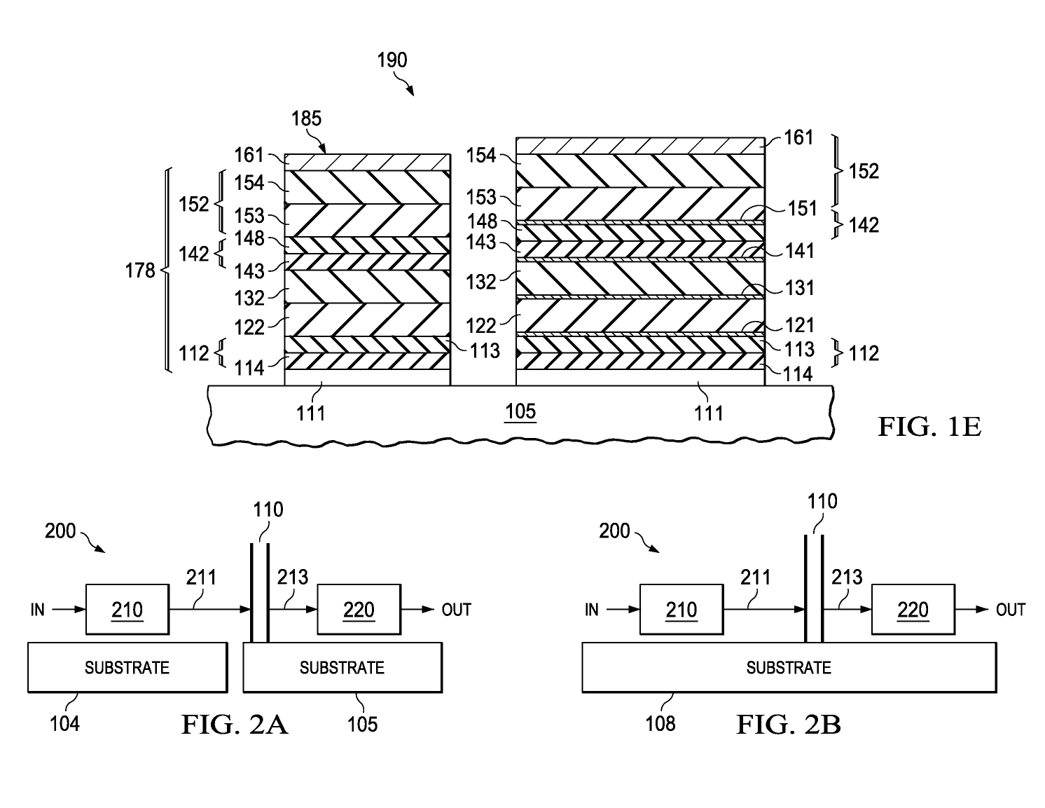

FIG. 1A shows a cross sectional view of an integrated circuit 100 comprising a isolation capacitor 110 according to an embodiment of the invention formed on a substrate 105, such as a substrate having a silicon surface. The isolation capacitor 110 comprises a bottom electrically conductive plate 111 in or on the surface, a multi-layer dielectric comprising stack 130 over the bottom plate 111, and a top electrically conductive plate 161 over the dielectric stack 130. Dielectric stack 130 comprises dielectrics 152, 142, 132, 122 and 112, which outside the capacitive isolator 110 on circuit 100 electrically isolate metal layers 161, 151, 141, 131, 121 (the bottom metal level; M1) and MOAT layer 111 from one another. Dielectric 152 comprises a dielectric such as a layer of silicon oxide (e.g. silicon dioxide) 153 and at least one layer of silicon nitride 154, which outside the capacitive isolator 110 on circuit 100 electrically isolates metal layer 151 from top metal 161. The total dielectric thickness of stack 130 is generally between 10 μm and 20 μm.

The layer of silicon nitride 154 is shown in FIG. 1A located immediately below the top plate 161. As used herein, “immediately below” or “immediately above” a top or bottom plate refers to a distance <50 angstroms away from the plate, and in one embodiment the nitride layer 154 and top plate 161 and/or bottom plate 111 are in direct physical contact. Nitride layer 154 being located immediately below the top plate 161 or immediately above the bottom plate (111 if FIG. 1A) has been found to improve the performance (e.g. BVrms and surge capability) of the isolation capacitor as compared to isolation capacitors built using conventional silicon oxide (e.g., silicon dioxide) as the only dielectric layer(s). In addition, in the embodiment shown in FIG. 1A the top metal level during wafer fabrication is used as the top plate 161 of the isolation capacitor 110.

Bottom plate 111 is shown comprising MOAT layer, which comprises an electrically conductive active layer that is formed in or on the semiconducting surface. MOAT layer can comprise N+ or P+ doped silicon (e.g. source, drain or body contact), or the gate conductor (e.g. silicide on doped polysilicon), respectively.

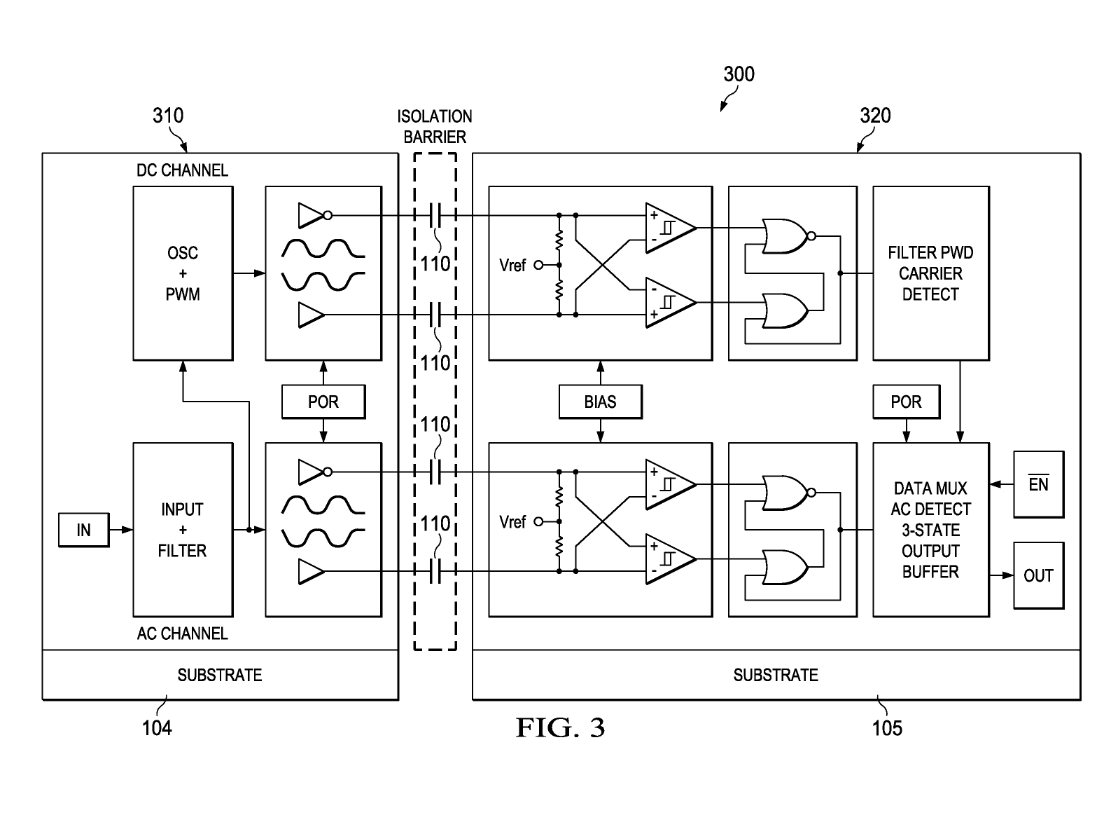

In one embodiment, the layers shown simply as “dielectric” in FIGS. 1A-E can all be silicon oxide layers. The respective metal layers 121, 131, 141, 151 and 161 can comprise aluminum, copper or other interconnect metal. The layers shown outside the capacitive isolator 110 on integrated circuit 100 can be used to form various devices and circuitry, such as the oscillators, filters, logic circuitry, comparators and buffers for input devices and output devices which can be coupled together by one or more isolation capacitors according to the invention (see FIGS. 2 and 3 described below).

Dielectric 112 is referred to as the pre-metal oxide and generally comprises a thermal or deposited oxide. When the dielectric comprises silicon oxide, this layer can be various silicon oxide layers, including layers derived from high-density plasma (HDP-CVD), TEOS derived oxide, BPSG, FSG or OSG.

Control of the deposition rate of the dielectric can provide dielectric layers that are neither significantly tensile nor compressive, such as having a stress between ±100 mPa, such as between ±60 mPa, or between ±10 mPa. Low stress in the dielectric layers helps minimize wafer bow. For example, in the case of plasma assisted reactors, such as PECVD reactors, silicon oxide, SiON and silicon nitride film stresses can be toggled using the RF power parameter. As the power is increased resulting in a deposition rate increase, film stress generally become more compressive and vice-versa.

FIG. 1B shows a cross sectional view of an integrated circuit 160 comprising an isolation capacitor 150 according to an embodiment of the invention having the same dielectric layers as isolation capacitor 110 shown in FIG. 1A. However, unlike isolation capacitor 110 shown in FIG. 1A, metal layer 121 forms the bottom plate of capacitive isolator 150.

FIG. 1C shows a cross sectional view of an integrated circuit 170 comprising an isolation capacitor 165 according to another embodiment of the invention. Isolation capacitor 165 includes a dielectric stack 172 which comprises dielectric 142 which includes a SiON layer 148 on another dielectric layer 143 (e.g. silicon oxide).

FIG. 1D shows a cross sectional view of an integrated circuit 180 comprising an isolation capacitor 175 according to another embodiment of the invention. Isolation capacitor 175 includes a dielectric stack which comprises two separate layers of silicon nitride 154 and 134, and two separate layers of SiON, layers 148 and 124. In one embodiment the respective nitride and SiON layers are between 0.3 μm and 10 μm thick, such as between 0.4 and 1.0 μm thick. Having layers of silicon nitride and SiON separated from one another generally facilitates etch processing, as opposed to single layers having the combined thickness of the respective layers.

FIG. 1E shows a cross sectional view of an integrated circuit 190 comprising an isolation capacitor 185 according to another embodiment of the invention, that is a modification of integrated circuit 170 shown in FIG. 1C. Isolation capacitor 185 includes a dielectric stack 178 which comprises two separate layers of silicon nitride 154 and 114, and one layer of SiON 148. Silicon nitride layer 154 is immediately below top plate 161 and silicon nitride layer 114 is immediately above bottom plate 111.

Capacitive isolators 170, 180 and 190 thus include a combination of oxynitride and nitride in addition to the other dielectric in the dielectric stack, such one or more silicon oxides. This arrangement has been found to significantly improve the electric field strength of the isolation capacitor, thereby enabling the isolation capacitor to provide higher breakdown voltage performance without the necessity of having extremely thick capacitor dielectrics (e.g. <18 μm), thus making the process more robust and manufacturable. Oxynitride has been found to primarily improve RMS breakdown voltage while the nitride has been found to primarily improve surge capability of the isolators.

Use of higher dielectric constant materials such as SiON (e.g., 4.4 to 6) and silicon nitride (e.g., 6 to 8) as compared to silicon dioxide (e.g., 3.9) has also been found to generally substantially reduces wafer manufacturability issues such as wafer bow and warp encountered during building known isolation capacitors, and also allows for fewer number of metal levels to accommodate the required capacitor dielectric thickness to obtain a given breakdown requirement which thus results in lower cost per wafer/die. Alternatives to SiON can include layers already available in certain process flows, such as SiC, SiCN and SiCO, as well as certain metal oxides (e.g. HfO₂).

A new process is also described herein for forming integrated circuits having isolation capacitors according to the invention. Besides forming new isolation capacitors by depositing the respective dielectric layers as described above, including integrating SiON and silicon nitride in the dielectric stacks, the conventional forming gas (N₂/H₂; near 400 C) transistor Vt stabilization sinter can be moved forward in the process to take place before deposition of any of the silicon nitride and SiON layers, or dielectrics other than silicon oxide, because layers such as silicon nitride and SiON can impede H₂ diffusion. For example, the stabilization sinter can be moved up in the process flow from before top metal processing to after first metal processing.

Isolation capacitors according to embodiments of the invention can be used in a wide variety of applications that can benefit from a robust, reliable on-chip isolation capacitors which can provide at least about 8 kVrms (11 kV peak) and ˜12 kV surge breakdown voltage, such as for industrial and process control applications which involve hazardous voltage environments. Other applications include high voltage, high-speed/high-precision communications, or communication over large distances. Common examples of such applications include industrial I/O systems, sensor interfaces, power supply/regulation systems, motor control/drive systems and Instrumentation. These applications can be found in a wide range of markets, including medical equipment, communication networks, plasma display panels and hybrid automotive vehicles.

FIG. 2A shows a block diagram of an integrated isolation capacitor comprising circuit 200 according to an embodiment of the invention. Isolation circuit 200 comprises first substrate 104 (e.g. Si) having an input network 210 formed thereon, and a second substrate 105 (e.g. Si) having isolation capacitor 110 and output network 220 formed thereon. Although not shown, isolation capacitor 105 can also be formed on first substrate 104 with input network 210. In assembly, one plate of capacitor 110 can be coupled to the output of input network 210. As a result, isolation capacitor 110 is interposed between the input network 210 and the output network 220. The input network 210 has circuitry operable for receiving an input signal (IN) and generating a processed input signal 211. The output network 220 has circuitry operable for receiving the processed input signal 213 and providing an output (OUT) for isolation circuit 200. The output network generally includes an output buffer. The input network can comprise an encoder so that the processed input signal 211 can comprise an encoded input signal, and the output network can comprise circuitry operable for decoding the encoded signal.

FIG. 2B shows a block diagram of an integrated isolation capacitor comprising circuit 250 according to an embodiment of the invention which is a single substrate version of isolation circuit 200. Isolation circuit 250 comprises a single dielectric substrate 108 having a semiconducting surface including input network 210, isolation capacitor 110, and output network 220 formed on the surface. In one embodiment dielectric substrate 108 can comprise a semiconductor (e.g. silicon) on insulator (SOI) substrate.

The isolation circuit can comprise a digital isolation circuit comprising at least one capacitively-coupled interconnect that capacitively communicates signals bi-directionally between an application device and a powered device. Both sides of the interconnects can include drivers that can be as simply implemented as one or move inverter stages. Digital signals can be modulated by a modulator for each transmitting portion of the interconnects then transferred across capacitors according to the invention that differentiate the communicated signal into leading and trailing pulses. Signals are received at drivers in the receiving portion of the interconnects and can be passed to a demodulator and logic for restoring the signals. In various configurations the receivers can be implemented as either single-ended or differential.

In one particular embodiment signaling across the isolation capacitor can comprise a non-encoded high signaling rate channel and a low signaling rate encoded channel, such as in a pulse width modulated (PWM) format. FIG. 3 shows a block diagram of an isolation capacitor comprising circuit 300 according to an embodiment of the invention having integrated circuits formed on substrates 104 and 105 implementing signaling across a plurality of isolation capacitors 110. Isolation circuit 300 includes an input network 310 that provides a non-encoded high signaling rate channel and a low signaling rate encoded channel in a pulse width modulated (PWM) format. Isolation capacitors 110 separate the logic in the input network 310 and the output buffer in the output network 320. Output network 320 receives the signals transmitted across the respective isolation capacitors 110.

The semiconductor substrates may include various elements therein and/or layers thereon. These can include barrier layers, other dielectric layers, device structures, active elements and passive elements including, source regions, drain regions, bit lines, bases, emitters, collectors, conductive lines, conductive vias, etc. Moreover, the invention can be based on a variety of processes including CMOS and BiCMOS.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and/or the claims, such terms are intended to be inclusive in a manner similar to the term “comprising.”

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the following claims.

1. An integrated circuit, comprising:
a substrate having a semiconducting surface, and
at least one isolation capacitor on said surface, said capacitor comprising:
a bottom electrically conductive plate formed in or over said surface;
a multi-layer dielectric comprising stack over said bottom plate, and
a top electrically conductive plate formed over said dielectric stack,
wherein said dielectric stack comprises at least one layer of silicon oxide and at least one layer of silicon nitride, and wherein said layer of silicon nitride is located immediately below said top plate or immediately above said bottom plate.

2. The integrated circuit of claim 1, wherein said dielectric stack further comprises a dielectric material other than said silicon oxide and silicon nitride.

3. The integrated circuit of claim 2, wherein said dielectric material comprises silicon oxynitride.

4. The integrated circuit of claim 3, wherein said dielectric stack comprises a plurality of said nitride layers and a plurality of said silicon oxynitride layers.

5. The integrated circuit of claim 3, wherein said layer of silicon oxynitride and said layer of silicon nitride are both between 0.3 μm and 2 μm thick.

6. The integrated circuit of claim 1, wherein said top plate comprises aluminum.

7. The integrated circuit of claim 1, wherein said top plate is a top level metal of said integrated circuit.

8. The integrated circuit of claim 1, wherein said bottom plate comprises a MOAT layer or a first level metal of said integrated circuit.

9. The integrated circuit of claim 1, wherein said top plate comprises copper.

10. The integrated circuit of claim 1, wherein said layer of silicon nitride comprises a first silicon nitride layer located immediately below said top plate and a second silicon nitride layer located immediately above said bottom plate.

11. The integrated circuit of claim 1, wherein said layer of silicon oxide has a stress between ±60 mPa.

12. An integrated circuit, comprising:
a substrate having a semiconducting surface, and
at least one isolation capacitor on said surface, said capacitor comprising:
a bottom electrically conductive plate formed in or over surface;
a multi-layer dielectric comprising stack over said bottom plate, and
a top electrically conductive plate formed over said dielectric stack,
wherein said dielectric stack comprises at least one layer of silicon oxide, at least one layer of silicon oxynitride and at least one layer of silicon nitride, and wherein said layer of silicon nitride is located immediately below said top plate or immediately above said bottom plate.

13. The integrated circuit of claim 12, wherein said layer of silicon oxynitride and said layer of silicon nitride are both between 0.3 μm and 2 μm thick.

14. The integrated circuit of claim 12, wherein said top plate is a top level metal of said integrated circuit.

15. An integrated circuit including isolation capacitors, comprising:
at least one substrate having a semiconducting surface;
an input network on said surface having circuitry operable for receiving an input signal and generating a processed input signal;
an output network on said surface having circuitry operable for receiving said processed signal and providing an output for said isolator, and
at least one isolation capacitor on said surface interposed between said input network and said output network, said capacitor comprising:
a bottom electrically conductive plate over said surface;
a multi-layer dielectric comprising stack over said bottom plate, and
a top electrically conductive plate formed over said dielectric stack,
wherein said dielectric stack comprises at least one layer of silicon oxide and at least one layer of silicon nitride, and wherein said layer of silicon nitride is located immediately below said top plate or immediately above said bottom plate.

16. The integrated circuit of claim 15, wherein said processed input signal comprises an encoded input signal, and said output network comprises circuitry operable for decoding said encoded signal.

17. The integrated circuit of claim 15, wherein said dielectric stack further comprises a dielectric material other than said silicon oxide and silicon nitride, wherein said dielectric material comprises silicon oxynitride.

18. The integrated circuit of claim 17, wherein said dielectric stack comprises a plurality of said nitride layers spaced apart from one another and a plurality of said silicon oxynitride layers spaced apart from one another.

19. The integrated circuit of claim 17, wherein said layer of silicon oxynitride and said layer of silicon nitride are both between 0.3 μm and 2 μm thick.

20. The integrated circuit of claim 15, wherein said at least one substrate comprises a first and a second substrate, wherein said input network is on said first substrate, said output network is on said second substrate, and said isolation capacitor is on said first or said seconds substrate.

21. A method of fabricating an integrated circuit including isolation capacitors, comprising:
providing a substrate having a semiconductor surface, and
fabricating at least one of said isolation capacitors on said surface, comprising:
forming a bottom electrically conductive plate in or on said surface;
forming a multi-layer dielectric comprising stack over said bottom plate, and
forming a top electrically conductive plate formed over said dielectric stack,
wherein said dielectric stack comprises at least one layer of silicon oxide and at least one layer of silicon nitride, and wherein said layer of silicon nitride is located immediately below said top plate or immediately above said bottom plate.

22. The method of claim 21, wherein said dielectric stack further comprises a dielectric material other than said silicon oxide and said silicon nitride, wherein said dielectric material comprises silicon oxynitride.

23. The method of claim 21, wherein said dielectric stack comprises a plurality of said nitride layers spaced apart from one another and a plurality of said silicon oxynitride layers spaced apart from one another.

24. The method of claim 22, wherein said layer of silicon oxynitride and said layer of silicon nitride are both between 0.3 μm and 2 μm thick.

25. The method of claim 21, further comprising a forming gas sinter at 370 C to 460 C, wherein said forming gas sinter is performed before said silicon nitride and said silicon oxynitride are formed.
